(19) United States
(12) Patent Application Publication
(10) Pub. No.: US 2007/0293169 A1
(43) Pub. Date: Dec. 20, 2007

(54) Method for controlling advertising content in an automobile

(76) Inventor: Frank S. Maggio, St. Petersburg, FL (US)

Correspondence Address: KING & SPALDING LLP, 1180 PEACHTREE STREET, ATLANTA, GA, 30309-3521, US

(21) Appl. No.: 11/452,482

(22) Filed: Jun. 14, 2006

(51) Int. Cl. H04B 1/18; H05K 11/00

(52) U.S. Cl. 455/152.1; 455/344

(57) ABSTRACT

A method for controlling advertising content in an automobile provides a sponsor of a digital radio system with the ability to provide occupants of an automobile with advertisements of the sponsor while eliminating other advertisements, including those of competitors. Sponsor advertisements can be transmitted to the digital radio receiver when the receiver is turned on, when a new channel is selected, and at intermittent times based on the amount of time the receiver has been on and the amount of time since the last advertisement was transmitted to the receiver. In addition, ad-free content can be provided with disc jockeys providing plugs that describe the products of the sponsor without providing standard ad content. The method further provides a system having multiple sponsors where information about the owner of the automobile is obtained and evaluated in order to select advertisements from sponsors having products of interest to the automobiles owner.

### FIELD OF THE INVENTION

The present invention relates to the fields of marketing and digital radio transmission services. In particular, the invention provides a method and system for controlling the advertising content that is transmitted to a digital radio listening audience.

### BACKGROUND OF THE INVENTION

For most people, the purchase of an automobile will be the second largest purchase they make during their lifetime, a home typically being the largest. Since most people purchase a new automobile every three to four years, this purchase will typically be repeated several times over a person's lifespan. Furthermore, as is true in other retail sectors, the ability of automobile manufacturers to retain a customer who currently owns one of their automobiles is generally less expensive than attracting new customers. However, competition for customers in the retail automobile market is very competitive. Each year, automobile manufacturers and their network of dealerships typically spend more money on advertising than many other industries.

Many automobile manufacturers attempt to influence a potential customer by providing a greater amount and a larger variety of advertisements than their competitors. They accomplish this by purchasing large amounts of advertising space on television, print media, billboards, internet advertising, and radio. Since each manufacturer of automobiles generally uses a similar marketing scheme, potential customers are inundated with advertisements from a variety of automobile manufacturers in a variety of media. Radio advertising is one of the most important forms of advertising used by automobile manufacturers. A large portion of the time a person spends listening to the radio is done in an automobile. Furthermore, in-automobile consumption of the content put out by the radio is generally higher than at other times when a customer may be listening to the radio, because there are generally fewer distractions to the customer and the customer is not able to leave the vicinity of the radio while in their automobile. Therefore, customer retention of radio advertising is generally higher while the customer is in the automobile than at other times when they are listening to the radio.

While previously considered optional equipment, most manufacturers consider AM/FM radios to be standard equipment installed in their automobiles. By providing radios in automobiles, manufactures, in effect, provide their competitors with a portal to market competing automobiles to their customer, thereby increasing the likelihood of losing the customer to a competitor when the customer purchases their next automobile. Automobile advertisements broadcast on the radio to a customer listening while riding in their automobile provide the customer with the ability to immediately compare the features of the automobile advertised to the one they are currently driving, thereby increasing the likelihood of increased attention to and retention of the advertisement. If it is assumed that advertising can impact future purchasing habits, the ability of an automobile manufacturer to limit the amount of competitive advertising, or increase the amount of its own advertising, to a current customer while the customer is driving the automobile would typically increase the likelihood that the current customer would purchase another vehicle from the same manufacturer as the current vehicle the customer is driving. Furthermore, the ability of a manufacturer to target or direct its advertising to a current customer as that customer's car ages and the customer closes in on the time they will purchase another automobile also would increase the likelihood that the customer will purchase another automobile from the same manufacturer.

Other retail sectors in other industries have also found radio advertising to be a successful way to reach consumers of their products. As with automobile advertising, competitors in each retail sector typically broadcast advertisements for competing products and services. Many of these retailers would find it beneficial to be able to continue to advertise their products to consumers in their automobiles over the radio, while preventing their competitors from providing competing advertisements. Like automobile manufacturers, large retailers, or retailers who have a large market in a particular geographic area may be able to support or subsidize a system that provides their advertisements to consumers while restricting competitive advertisements. On the other hand, smaller retailers providing distinct products or services may be able to team up to provide a similar service. To get the greatest benefit from the system, each retailer would want to target its advertising to those consumers who are likely to purchase their product or service.

Digital (or satellite) radio currently broadcast by third party digital radio or Internet service providers is an option provided by some automobile manufacturers. Customers who choose to pay the additional cost for digital radio generally enjoy the more diverse and targeted selection of programming provided, delivered in a superior audible format as compared to that of traditional AM or FM radio. These customers also tend to prefer digital radio because, currently, many digital radio stations do not provide significant advertising content to its listening audience. While an automobile manufacturer could eliminate the potential for their customers hearing competitors' advertising while in their automobile by installing a conventional digital radio, the automobile manufacturer would also be foreclosed from advertising to their customers via the digital radio.

In view of the foregoing, there is a need in the art for a method to allow an automobile manufacturer to transmit targeted advertising from the manufacturer to a user of the manufacturer's automobile via a digital radio receiver installed in the automobile, while preventing the transmission of competitive advertising to the same automobile. Furthermore, there is a need in the art for a method of increasing the amount of targeted advertising from the automobile manufacturer (or an unrelated advertiser willing to provide consideration to the automobile manufacturer) to a current customer of a new or aging automobile, via a digital radio receiver installed in the customer's automobile. In addition, there is a need in the art for a method for obtaining demographic and consumer preference information about the purchaser of an automobile having a digital radio receiver and transmitting targeted advertising to the purchaser via the digital radio receiver based on the demographic and consumer preference information of the purchaser. Furthermore, there is a need in the art for a method for obtaining sponsorship for a digital radio service and providing targeted advertising related to the sponsor to the occupant of the automobile having a digital radio receiver subsidized by the sponsor.

### SUMMARY OF THE INVENTION

A system for advertising content control in an automobile provides methods and architecture for restricting or controlling the content and frequency of advertisements that are transmitted to digital or satellite radio receivers installed in automobiles. An automobile manufacturer typically controls the system and installs digital radio receivers in the automobiles that they manufacturer. The digital radio receivers can be limited to receiving content provided by the automobile manufacturer, including digital radio feeds and advertising sponsored by the automobile manufacturer or selected advertisers. The digital radio feeds can include different varieties of music, sports, news, and talk radio. The advertising content can include information about products offered by the manufacturer and its network of dealers, local and national news, and other content that may be of interest to the occupants of the vehicle.

The digital radio receiver can also be limited to receiving content from sponsors of the system other than the manufacturer of the automobile. These other sponsors will typically only sponsor the system of a limited geographic area such that a country the size of the United States of America may have multiple sponsors of the system. However, these “local” sponsors would typically control all of the advertising content provided to the digital radio receiver, including advertisements for the local sponsors' products and/or services.

The digital radio receiver can also be limited to receiving content from a pool of sponsors. Like the system for content control by the automobile manufacturers, the sponsor pool system would typically cover a large geographic area, such as a country or region of the world. Information about the owner of the automobile in which the digital radio receiver is installed would typically be obtained. The information could include demographic and product preference information for the owner. The information can also include demographic and product preference information for people living in the same residence as the owner of the automobile. Demographic information typically includes the age, race, occupation, education, and salary of a person. Product preference information can include products a person buys, products they are interested in buying in the future and products they want additional information about. This information can be used to determine products offered by sponsors in the sponsor pool that are likely to be of interest to the occupants of the automobile. This information can be stored in databases for evaluation by the system in order to determine which advertising content to transmit to the digital radio receiver.

The digital radio receiver can also include an identification code. The identification code can be unique to the digital radio receiver or it can be unique to the sponsor of the system if the sponsor is a local sponsor. The identification code can be associated in a database with the advertisements previously transmitted to the digital radio receiver. The identification code can also be associated with the demographic and product preference information for the owner of the automobile in which the digital radio receiver is installed and their family. Furthermore, the identification code can be associated with one or more run time clocks. The run time clocks can record the amount of time that the digital radio receiver has been on for a single session, the amount of time since the last advertisement was transmitted or received at the digital radio receiver, or the amount of time since a particular advertisement was transmitted or received at the digital radio receiver.

For one aspect of the present invention, upon activation of the digital radio receiver, an advertisement sponsored by the manufacturer can be transmitted to the digital radio receiver for play in the automobile. Then a streaming signal for the digital radio feed selected by an occupant of the automobile is typically transmitted to the digital radio receiver once the advertisement has concluded. The streaming signal can continue being transmitted in an uninterrupted manner to the digital radio receiver until the receiver is turned off.

For another aspect of the present invention, a local sponsor for the digital radio service is obtained. The local sponsor will typically subsidize all or a portion of the cost for the digital radio service, the digital radio receiver and the installation of the receiver into the automobile. The local sponsor can be obtained by an automobile dealership that sells the automobile with the installed digital radio receiver. The automobile can then be sold to an end user. Upon receiving a signal that the digital radio receiver, the digital radio receiver can transmit its identification code to a digital radio provider service. The identification code can be associated either with the digital radio receiver or the local sponsor. Once turned on, a streaming signal for a digital radio feed can be transmitted to the digital radio receiver. A run clock is typically activated to record the amount of time that the digital radio receiver has been turned on. Once a predetermined amount of time has passed, typically based on an evaluation of the run clock, an advertisement related to the local sponsor is retrieved from a database.

The database could be at the transmission location or it could actually be buffered within a hard drive located onboard the vehicle. This database and content could be buffered overnight while the vehicle is not in use. This buffering could also allow the transmission provider to download to the vehicle content targeted to the listener based on stated preferences, or even based on prior music or content selected by the listener. For example, software within the system may note that the listener listened to several John Cougar Mellencamp songs, but changed stations whenever the Go-Go's came on. In this example, the system may determine that it will no longer download Go-Go's songs and that it will download additional John Cougar Mellencamp songs or songs similar to Mellencamp. The selected advertisement is typically based on the identification code from the digital radio receiver. The advertisement can then be played on the digital radio receiver. After the advertisement concludes, the digital radio receiver typically begins playing the streaming signal transmitted by the digital radio provider service or the buffered content and ads stored in the hard drive.

For another aspect of the present invention, a group of sponsors is obtained to subsidize all or a portion of the cost for the digital radio service, the digital radio receiver, and the installation of the receiver into the automobile. Typically, each sponsor in the group will provide products and/or services that are separate and distinct from other sponsors in the group. An automobile is sold to an end-user with the digital radio receiver installed. Demographic and consumer preference information about the end-user can be obtained. This information typically is obtained at the time the automobile is purchased, however, it can be obtained later though Internet, telephonic, or standard mail surveys or by obtaining the information from third party organizations. The information is typically associated in a database with the identification code of the digital radio receiver. When the digital radio receiver is turned on a signal can be sent to the digital radio service provider that includes the identification code and the fact that the receiver was activated. The demographic and consumer preference information can be evaluated and an advertisement is typically selected based on that information. The advertisement can then be transmitted to the digital radio receiver or the ad can be stored in the hard drive. Once the advertisement has concluded the digital radio service provider typically transmits the streaming signal for the radio feed selected on the digital radio receiver or the buffered content and ads stored in the hard drive resumes playing.

For another aspect of the present invention an automobile manufacturer can provide an automobile with a digital radio receiver installed that only receives advertising content sponsored by the automobile manufacturer. The digital radio receiver typically includes an identification code that is associated with the age or model year of the vehicle. When the digital radio receiver is activated, the identification code can be transmitted to the digital radio service provider which typically transmits a streaming signal for the digital radio feed selected on the receiver. A run clock can be associated with the receiver and activated to record the time the receiver has been turned on. Advertisements sponsored by the manufacturer of the automobile can be played intermittently based on a predetermined amount of time. As the automobile gets older, an evaluation of the identification code will lower the predetermined amount of time so that advertisements sponsored by the automobile manufacturer will be played more frequently. At the conclusion of each advertisement, transmission of the streaming signal from the digital radio service provider can resume or the buffered content and ads stored in the hard drive can resume playing.

For yet another aspect of the present invention an automobile manufacture can enter into an agreement with a satellite radio service provider. As part of this agreement, the service provider would stream multiple types of radio station genres to cars manufactured by the automobile manufacturer. Also, as part of the agreement, the cost of the receiver units may be all or partially subsidized by the automobile manufacture and the service provider. Each station, when distributed by the service provider, would include a limited amount of commercials for the automobile manufacture. The installed receiver would only be able to receive the stations, and the corresponding limited advertising, specifically transmitted for the automobile manufacturer. Furthermore, the disc jockeys for these stations could provide additional advertising value for the automobile manufacturer by “plugging” the automobile manufacturer or reminding the listener that the free digital radio that they are listening to was brought to them by the automobile manufacturer. For example, the disc jockey could say, “you're listening to XYZ (name of the automobile manufacturer) radio, maker's of the new FLASH model featuring xenon lights and Freon-free air conditioning and starting at a price of $19,900.”

### BRIEF DESCRIPTION OF DRAWINGS

For a more complete understanding of exemplary embodiments of the present invention and the advantages thereof, reference is now made to the following description in conjunction with the accompanying drawings in which:

FIG. 1 is a block diagram illustrating an exemplary system for implementation of various embodiments of the present invention;

FIG. 2 is a flowchart illustrating a process for transmitting an advertisement upon activation of a digital radio receiver in accordance with an exemplary embodiment of the present invention;

FIG. 3 is a flowchart illustrating a process for providing digital radio service at a reduced rate in exchange for targeted advertising in accordance with an exemplary embodiment of the present invention;

FIG. 4 is a flowchart illustrating a process for intermittently transmitting targeted advertising to a digital radio receiver in accordance with an alternative exemplary embodiment of the present invention;

FIG. 5 is a flowchart illustrating a process for transmitting an advertisement to a digital radio receiver upon determining that the selected radio feed has been changed in accordance with an alternative exemplary embodiment of the present invention;

FIG. 6 is a flowchart illustrating an alternate process for transmitting an advertisement to a digital radio receiver upon determining that the selected radio feed has been changed in accordance with the alternative exemplary embodiment of the present invention;

FIG. 7 is a flowchart illustrating a process for obtaining sponsorship for a digital radio service and providing targeted advertising related to the sponsor in accordance with an alternative exemplary embodiment of the present invention;

FIG. 8 is a flowchart illustrating a process for obtaining and transmitting targeted advertising to a digital radio receiver based on the consumer preferences or demographic information of the owner of the digital radio receiver in accordance with an alternative exemplary embodiment of the present invention; and

FIG. 9 is a flowchart illustrating a process for modifying the rate of targeted advertising provided to a digital radio receiver based on the age of the vehicle in which the receiver is installed in accordance with an alternative exemplary embodiment of the present invention.

### DETAILED DESCRIPTION OF THE EXEMPLARY EMBODIMENTS

The present invention supports a method and system for transmitting targeted advertising to digital radio receivers installed in vehicles based on the manufacturer of the vehicle, the age of the vehicle, the sponsor of the digital radio service, or the consumer preference or demographic data of the owner of the vehicle. Exemplary embodiments of the invention can be more readily understood by reference to the accompanying figures.

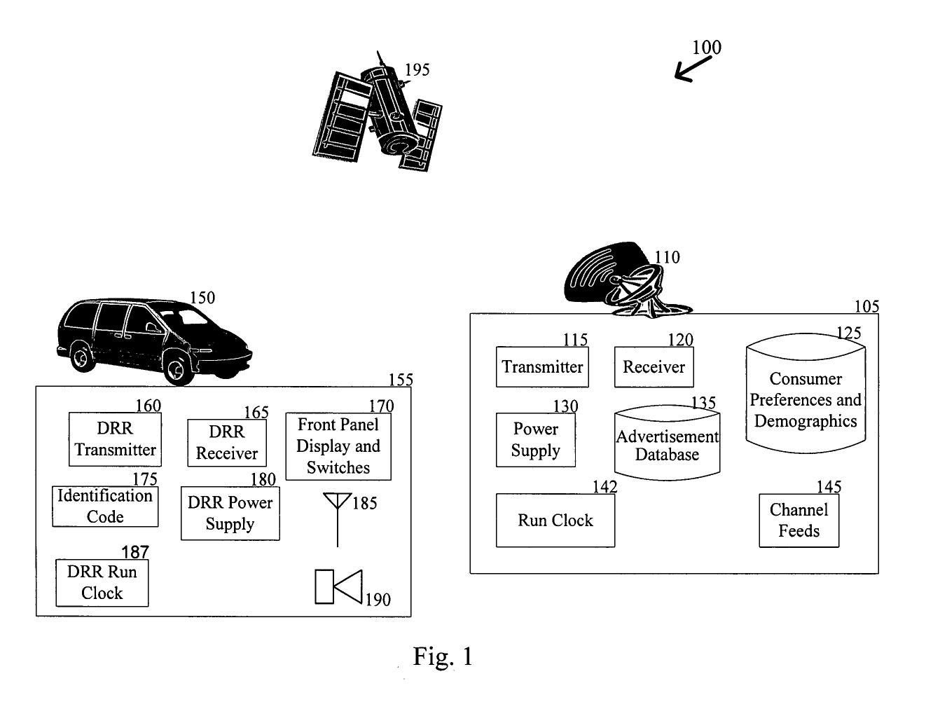

Referring now to the drawings, in which like numerals represent like elements throughout the several figures, aspects of the present invention and an exemplary operating system for the implementation of the present invention will be described. FIG. 1 is a block diagram illustrating a system 100 for remotely transmitting targeted advertising to a digital radio receiver (“DRR”) from a digital radio service provider (“DRSP”) constructed in accordance with an exemplary embodiment of the present invention. The exemplary system 100 comprises a digital radio provider system (“DRPS”) 105, an automobile 150 comprising a DRR 155, and a satellite 195. The DRPS 105, which is well known in the art, typically provides one or more digital radio channel feeds 145 in a signal stream for transmission or broadcast to one or more DRRs 155 using an RF signal. The DRPS 105 includes functional components such as a transmitter 115, receiver 120, consumer preferences and demographics database 125, power supply 130, advertisement database 135, one or more run clocks 142, and channel feeds 145. The power supply 130 provides electrical power for the operation of the transmitter 115, receiver 120, consumer preferences and demographics database 125, advertisement database 135, one or more run clocks 142, and one or more channel feeds 145.

The signal stream from the digital channel feeds 145 is typically provided to a transmitter 115 which transmits the signal stream through the antenna 110 to the DRR 155. The DRPS 105 is also capable of receiving information though the antenna 110 which is passed to the receiver 120. Although the antenna 110 is shown for broadcast via an orbiting satellite 195 in this illustration, it will be appreciated that the invention can be adapted for use with other communication media, including terrestrial broadcast without the need for a satellite 195, telephone, and computer networks.

For example, in a alternative embodiment, an automobile manufacturer can install a radio with a browser that is capable of receiving Internet or WiMAX radio stations loaded with the browser. WiMAX is a standards-based wireless technology that provides high-throughput broadband connections over long distances. WiMAX can be used for a number of applications, including “last mile” broadband connections, hotspots and cellular backhaul, and high-speed enterprise connectivity. In this alternative embodiment, the radio effectively tunes into an IP address (converted to numbers for ease of incorporation into radio jargon). The radio can include numerous wireless-fidelity (“wi-fi”) or broadband wi-fi stations that can be controlled by the automobile manufacturer. Because this alternative embodiment includes a two-way communication system, the alternative embodiment allows for dynamic insertion of ads very easily, regardless of the station to which a user listens. For example, with the alternative system, the automobile manufacturer would have the ability to “road block” or provide a single ad across all stations at the same time (which drastically limits ad skipping) by synchronizing radio content and filler, such as news traffic, and weather, so that the ads all come at the same time.

Additionally, although audio sources are shown and described, the invention can be adapted for use with other types of sources as well, such as video or other data. In one exemplary embodiment, the transmitter 115 and the receiver 120 can comprise separate components, each individually performing their functions. Alternatively, the transmitter 115 and receiver 120 can comprise a single component performing both transmitting and receiving functions.

The consumer preferences and demographics database 125 is communicably attached to the transmitter 115, receiver 120, and advertisement database 135. The consumer preferences and demographics database 125 typically comprises a plurality of database tables that comprise ID codes, demographic information related to the consumer and the family of the consumer who purchased the automobile 150, and consumer preferences for the consumer and the family of the consumer who purchased the automobile 150. In one exemplary embodiment, the consumer preference and demographics database 125 is communicably attached to the transmitter 115, receiver 120 and advertisement database via a processor (Not Shown). The advertisement database 135 is communicably attached to the transmitter 115, receiver 120, consumer preferences and demographics database 125, and run clock 142. The advertisement database 135 typically comprises a plurality of database tables that comprise ID codes, one or more advertisements, run clock timing for one or more ID codes, and a listing of advertisements transmitted to each DRR based on the provided ID code 175. In one exemplary embodiment, the advertisement database 135 is communicably attached to the transmitter 115, receiver 120 and consumer preference and demographics database 125 via a processor (Not Shown).

The DRPS 105 can also comprise one or more run clocks 142. The run clocks can be communicably attached to the advertisement database 135 via a processor (Not Shown). The run clock 142 typically functions as a timer to record the amount of time that has expired since the previous advertisement was transmitted to the DRR 155. In this embodiment, each of the plurality of DRRs 155 would typically require its own run clock 142 while the DRR 155 was activated. In an alternative embodiment, the run clock 142 records the amount of time that has expired since a particular advertisement was transmitted to the DRR 155 for a system 100 that includes a variety of advertisements in the advertisement database 135. In this alternative embodiment, each DRR 155 can require more than one run clock 142 to record the elapsed time since each advertisement was transmitted to the DRR 155. The channel feeds 145 are communicably attached to the transmitter 115 and the receiver 120 via a processor (Not Shown). The channel feeds 145 typically provide one or more channels of digital audio programming. The channel feeds 145 can include, but are not limited to, different audio feeds for music, news, sports, and talk radio.

The DRR 155 can be installed in an automobile 150. The automobile 150 can include any version of vehicle used to transport occupants from one location to another. In an alternative embodiment, the DRR 155 includes the capability to be removed from the automobile 150 and attached to a portable or stationary base unit (Not Shown) for operation outside of the automobile 150. The DRR 155 typically comprises a DRR transmitter 160, a DRR receiver 165, a front panel display and switches 170, an ID code 175, a DRR power supply 180, a DRR antenna 185, and one or more speakers 190. As with the DRPS 105, in one exemplary embodiment, the DRR transmitter 160 and the DRR receiver 165 can comprise separate components, each individually performing their functions. Alternatively, the DRR transmitter 160 and DRR receiver 165 can comprise a single component performing both transmitting and receiving functions.

In another exemplary embodiment, the DRR 155 could include a hard drive (Not Shown) and a database within the hard drive. Content for the DRR 155 could be buffered in the database while the DRR 155 is not in use. The buffering could also allow the transmission provider to download to the vehicle 150 content targeted to the listener, based on stated preference or based on prior music or content selected by the listeners. For example software communicably connected to the DRR 155 or within the DRR 155 could determine that a listener listened to multiple songs by a first artist but changed stations when a second artist began to play a song. The software could then download into the buffer additional songs from the first artist (and those who play songs similar to the first artist) while not adding any songs by the second artist to the buffer.

The power supply 180 provides electrical power for the operation of the DRR transmitter 160, DRR receiver 165, front panel display and switches 170, the ID code 175, and the speakers 190. The DRR antenna 185 is of similar make as those well known in the art and capable of transmitting and receiving information at a DRR 155 from a DRPS 105.

The DRR transmitter 160 is communicably attached to the front panel display and switches 170, the ID code 175, the DRR antenna 185, and the DRR run clock 187. The DRR transmitter 160 can transmit the ID code 175, information related to a change of the selected channel feed made at the front panel display and switches 170, and/or results from timing recorded at the DRR run clock 187 to the DRPS 105 through the DRR antenna 185. The DRR transmitter 160 is also capable of transmitting information related to the powering on or off of the DRR 155 to the DRPS 105.

The DRR receiver 165 is communicably attached to the front panel display and switches 170, the DRR antenna 185, and the speakers 190. A signal can be received at the DRR antenna 185 from the antenna 110 or via the satellite 195. The signal is passed from the DRR antenna 185 to the DRR receiver 165 for processing of the signal, such processing being well known in the art. The signal can then be passed from the DRR receiver 165 to one or more speakers 190. The speakers 190 can be physically attached to the DRR 155 or, in an alternative embodiment, the speakers 190 can be distributed throughout the automobile 150.

The front panel display and switches 170 is communicably attached to the DRR transmitter 160 and the DRR receiver 165. The front panel display and switches provide a user the ability to change the selected channel feed, adjust the volume, tone, or bass of the channel feed, as well as other functions which are well known in the art. The ID code 175 is communicably attached to the DRR transmitter 160. The ID code is typically constructed of digital data that provides a unique identifier for the DRR 155 that distinguishes it from other DRR's 155. In an alternative embodiment, the ID code 175 identifies the sponsor of the system 100. The ID code 175 is capable of being transmitted with or without additional information from the DRR 155 to the DRPS 105, where the ID code 175 can be evaluated to identify the particular DRR 155 that is transmitting information.

While the exemplary embodiment envisions one or more run clocks 142 at the DRPS 105, in an alternative embodiment, the DRR 155 can include a DRR run clock 187. The DRR run clock 187 can be communicably attached to the DRR transmitter 160. The DRR run clock 187 typically functions as a timer to record the amount of time that has expired since the previous advertisement was transmitted to the DRR 155. In an alternative embodiment, the DRR run clock 187 records the amount of time that has expired since a particular advertisement was transmitted to the DRR 155 for a system 100 that includes a variety of advertisements being transmitted to the DRR 155. In this alternative embodiment, each DRR 155 can require more than one DRR run clock 187 to record the elapsed time since each advertisement was transmitted to the DRR 155. In another alternative embodiment, the run clocks 142 or the DRR run clock 187 records the amount of time the DRR 155 has been active for a single session.

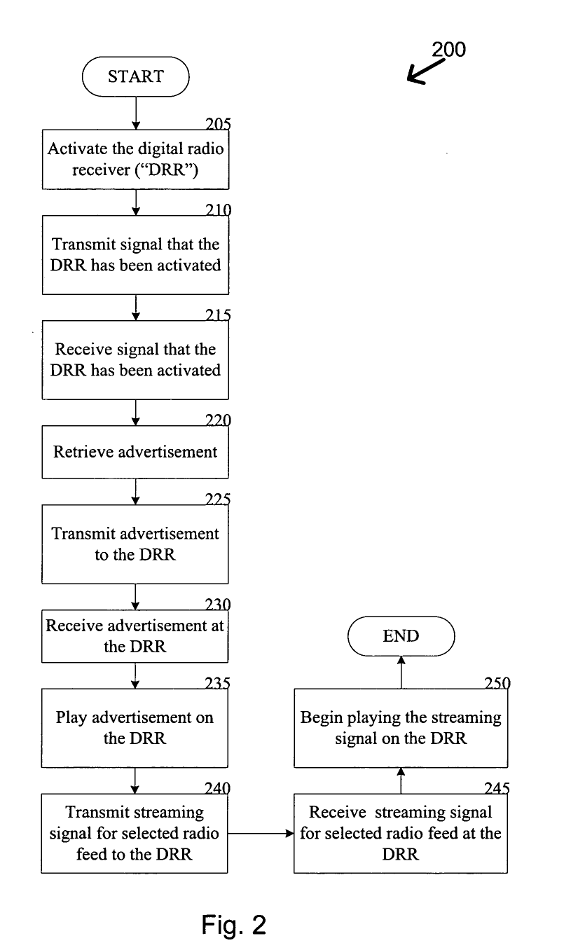

FIGS. 2-9 are logical flowchart diagrams illustrating the exemplary methods for transmitting targeted advertisements to one or more DRRs 155. FIG. 2 is a logical flowchart diagram presented to illustrate the general steps of an exemplary process 200 for transmitting an advertisement to a DRR 155 upon activation of the DRR 155, within the operating environment of the exemplary transmission and receiving system 100 of FIG. 1.

Now referring to FIGS. 1 and 2, the exemplary method 200 begins at the START step and proceeds to step 205, where the DRR 155 is activated. The DRR typically becomes activated when the DRR power supply 180 receives an electrical current from the automobile 150 and passes that electrical current to the remainder of the DRR 155. In one exemplary embodiment, the DRR 155 is located and installed in an automobile. In this exemplary embodiment, the DRR 155 can be activated by a driver/passenger in the automobile 150 turning a power knob or pushing a power button on the front panel display and switches 170. In another exemplary embodiment the DRR 155 can activate when a key is placed in the ignition of the automobile 150 or the automobile 150 is started.

In step 210, the DRR 155 transmits a signal that the DRR 155 has been activated. The DRR 155 typically transmits this information by sending a signal from the DRR transmitter 160 through the DRR antenna 185 to the antenna 110, by way of the satellite 195. The DRPS 105 receives the signal that the DRR 155 has been activated through the antenna 110 to the receiver 120 in step 215. In another exemplary embodiment, the DRPS 105 could send a continuous series of pings to the DRR 155 to determine if the DRR 155 has been activated. In step 220, the DRPS 105 retrieves an advertisement from the advertisement database 135. The advertisement is typically passed from the advertisement database 135 to the transmitter 115 for transmission. In one exemplary embodiment, all of the advertisements in the advertisement database 135 will be advertisements for the manufacturer of the automobile 150 that the DRR 155 is installed in. In another exemplary embodiment, the advertisement database 135 contains advertisements and information provided by or sponsored by the manufacturer of the automobile 150 in which the DRR 155 is installed.

In step 225, the DRPS 105 transmits the retrieved advertisement by passing it from the transmitter 115 to the antenna 110, and on to the DRR 155, by way of the satellite 195. In an alternative embodiment, buffered content and ads stored in the hard drive or the DRR 155 are retrieved and played on the DRR 155. Returning to the exemplary embodiment, the DRR 155 receives the advertisement at the DRR antenna 185 and DRR receiver 165 in step 230. In step 235 the DRR 155 plays the advertisement. In one exemplary embodiment, the DRR 155 plays the advertisement by passing the advertisement from the DRR receiver 165 to one or more speakers 190. In step 240, the DRPS 105 transmits a streaming signal for the selected radio feed to the DRR 155. In one exemplary embodiment, the selected radio feed is the digital station that an occupant of the automobile 150 has chosen to listen to. The streaming signal for the channel feed can be retrieved from the channel feed supply 145 and passed to the transmitter 115 and antenna 110 for transmission to the DRR 155 by way of the satellite 195. In an alternative embodiment, the channel feed can be retrieved from the content stored in the buffered database on the hard drive within the DRR 155.

The DRR 155 receives the streaming signal for the selected radio feed from the DRPS 105 or satellite 195 in step 245. The DRR 155 typically receives the streaming signal at the DRR antenna 185 and passes the signal to the DRR receiver 165. In step 250, the DRR 155 begins playing the received streaming signal for the selected radio feed. In one exemplary embodiment, the DRR 155 plays the streaming signal by passing the signal from the DRR receiver 165 to one or more speakers 190. The process then continues to the END step.

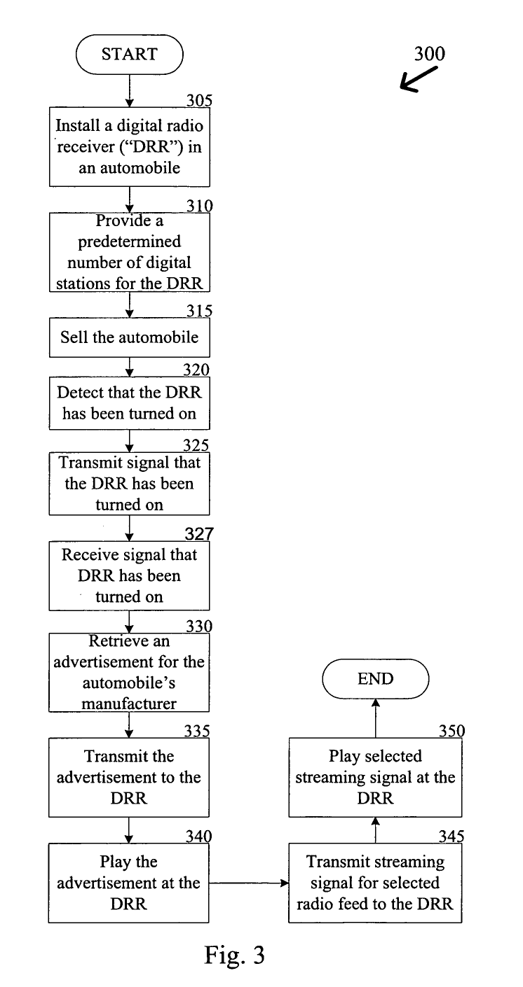

FIG. 3 is a logical flowchart diagram presented to illustrate the general steps of an exemplary process 300 for providing digital radio service at a reduced rate in exchange for providing targeted advertising through the DRR 155, within the operating environment of the exemplary transmission and receiving system 100 of FIG. 1. Referencing FIGS. 1 and 3, the exemplary method 300 begins at the START step and continues to step 305, where the DRR 155 in installed in an automobile 150. In one exemplary embodiment, the DRR 155 is installed in the automobile 150 at the assembly factory for the manufacturer of the automobile 150, however, the DRR 155 could also be installed in the automobile 150 at the automobile dealership, at a retail supplier of the DRR 155, or at a factory authorized installer of the DRR 155.

In step 310, a predetermined number of digital channel feeds are programmed into the DRR 155. The digital channel feeds are typically programmed into the DRR receiver 165. The predetermined number of channel feeds can be any number greater than zero, however, the number of channel feeds can be limited by the total amount of bandwidth available to a digital radio service provider. In one exemplary embodiment, the manufacturer of the automobile 150 provides the DRR 155 to purchasers of the manufacturer's automobile 150 for free or at a rate below the retail cost of the DRR 155. The automobile manufacture also secures a number of digital channel feeds from a digital radio service provider that are separate from the digital radio feeds provided to subscribers to the digital radio service provider. In one exemplary embodiment, the separate digital radio feeds can be transmitted only to DRRs 155 that are installed in the manufacturer's automobiles 150.

In step 315, the automobile 150 containing the DRR 155 is sold to a consumer. The automobile 150 is typically sold to the consumer at an automobile dealership. The DRR 155 detects that it has been turned on, or activated, in step 320. The DRR typically detects that it has been turned on when the DRR power supply 180 receives an electrical current from the automobile 150 and passes that electrical current to the remainder of the DRR 155. In one exemplary embodiment, the DRR 155 detects that it has been turned on when an occupant in the automobile 150 turns a power knob or pushes a power button on the DRR front panel display and switches 170. In another exemplary embodiment the DRR 155 can detect that it has been turned on when a key is placed in the ignition of the automobile 150 or the automobile 150 is started and the DRR 155 was left on the last time the automobile 150 was in use.

In step 325, the DRR 155 transmits a signal that the DRR 155 has been turned on. The DRR typically transmits this information by sending a signal from the DRR transmitter 160 through the DRR antenna 185 to the antenna 110, by way of the satellite 195. The DRPS 105 receives the signal that the DRR 155 has been turned on through the antenna 110 to the receiver 120 in step 327. In step 330, the DRPS 105 retrieves an advertisement from the advertisement database 135 for the automobile's manufacturer 330. The advertisement for the automobile's manufacture can include, but is not limited to, an advertisement to buy an automobile manufactured by the same manufacturer, a news bulletin sponsored by the manufacturer of the automobile 150, or other information that may be of interest to the occupants of the automobile 150. In an alternative embodiment, the DRR 155 can retrieve the advertisement for the automobile's manufacture from the buffered content stored in the hard drive of the DRR 155 and the DRR 155 plays the ad.

In step 335, the DRPS 105 transmits the retrieved advertisement to the DRR 155. In one exemplary embodiment, the DRPS 105 transmits the advertisement by passing it from the advertisement database 135 to the transmitter 115, to the antenna 110, and on to the DRR 155, by way of the satellite 195. The DRR 155 receives the advertisement and plays the it on the DRR 155 in step 340. In one exemplary embodiment the DRR 155 receives the advertisement at the DRR antenna 185 and DRR receiver 165 and plays the advertisement by passing the advertisement from the DRR receiver 165 to one or more speakers 190. In step 345, the DRPS 105 transmits a streaming signal for the selected radio feed to the DRR 155. The streaming signal for the channel feed is typically retrieved from the channel feed supply 145 and passed to the transmitter 115 and antenna 110 for transmission to the DRR 155 by way of the satellite 195. In an alternative embodiment the feed for the channel feed is stored in the buffered content in the hard drive of the DRR 155.

The DRR 155 receives the streaming signal for the selected radio feed and plays the streaming signal in step 350. The DRR typically receives the streaming signal at the DRR antenna 185 and passes the signal to the DRR receiver 165, which plays the received streaming signal for the selected radio feed by passing the signal from the DRR receiver 165 to one or more speakers 190. The process then continues to the END step.

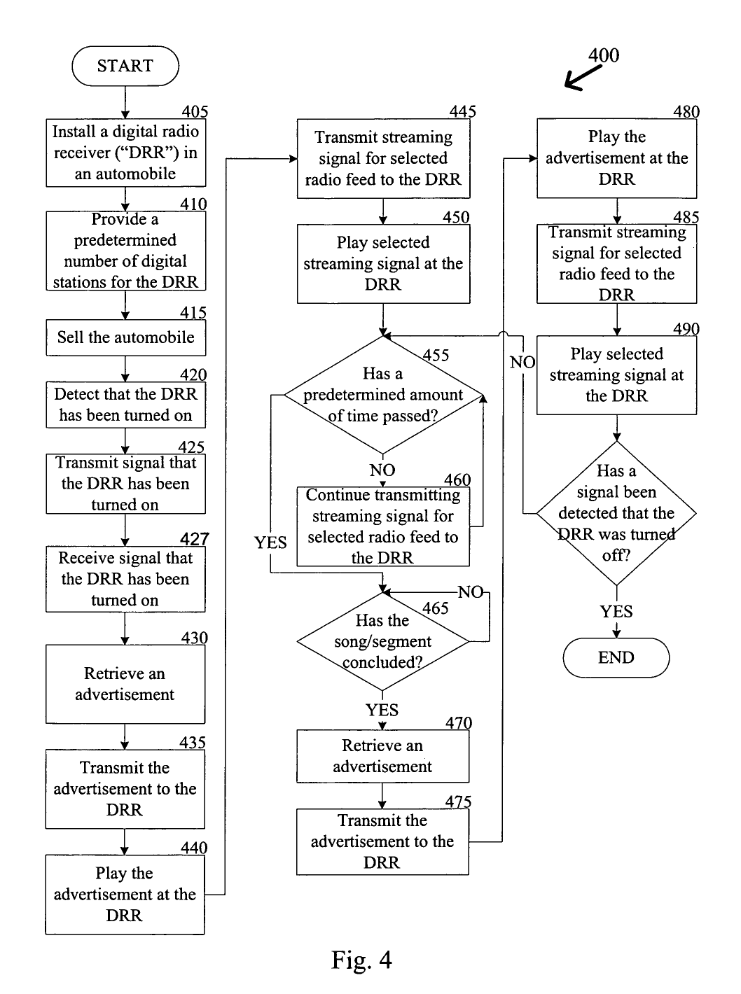

FIG. 4 is a logical flowchart diagram presented to illustrate the general steps of an exemplary process 400 for intermittently transmitting targeted advertising to a DRR 155, within the operating environment of the exemplary transmission and receiving system 100 of FIG. 1. Referencing FIGS. 1 and 4, the exemplary method 400 begins at the START step and continues to step 405, where the DRR 155 in installed in an automobile 150. In step 410, a predetermined number of digital channel feeds is programmed into the DRR 155. In step 415, the automobile 150 containing the DRR 155 is sold to a consumer. The DRR 155 detects that it has been turned on in step 420.

In step 425, the DRR 155 transmits a signal that the DRR 155 has been turned on. The DRR 155 typically transmits this information by sending a signal from the DRR transmitter 160 through the DRR antenna 185 to the antenna 110, by way of the satellite 195. The DRPS 105 receives the signal that the DRR 155 has been turned on through the antenna 110 to the receiver 120 in step 427. In step 430, the DRPS 105 retrieves an advertisement from the advertisement database 135 for the automobile's manufacturer. The advertisement for the automobile's manufacture can include, but is not limited to, an advertisement to buy an automobile manufactured by the same manufacturer, a news bulletin sponsored by the manufacturer of the automobile 150, or other information that may be of interest to the occupants of the automobile 150. In another exemplary embodiment, the advertisement is stored in the buffered content of the hard drive of the DRR 155, where it is retrieved by the DRR 155 and played.

In step 435, the DRPS 105 transmits the retrieved advertisement to the DRR 155 by passing it from the advertisement database 135 to the transmitter 115, to the antenna 110, and on to the DRR 155, by way of the satellite 195. The DRR 155 receives the advertisement and plays it on the DRR 155 in step 440 by receiving the advertisement at the DRR antenna 185 and DRR receiver 165 and playing the advertisement on one or more speakers 190. In step 445, the DRPS 105 transmits a streaming signal for the selected radio feed to the DRR 155. The streaming signal for the channel feed is typically retrieved from the channel feed supply 145 and passed to the transmitter 115 and antenna 110 for transmission to the DRR 155 by way of the satellite 195. In an alternative embodiment, the channel feed is stored in the buffer of the hard drive in the DRR 155, retrieved by the DRR 155 and played for the listener.

Returning to the exemplary embodiment, the DRR 155 receives the streaming signal for the selected radio feed at the DRR receiver 165 and plays the streaming signal on one or more speakers 190 in step 450. An inquiry is conducted in step 455 to determine if a predetermined amount of time has passed. The predetermined amount of time can be any amount from zero seconds to an infinite amount of minutes. In one exemplary embodiment, the predetermined amount of time is ten, twenty, and thirty minutes.

The predetermined amount of time can be determined by evaluating the DRR run clock 187 or run clock 142. In one exemplary embodiment, the DRR run clock 187 tracks the amount of time the DRR 155 has been continuously on, or active, for the current session. In another exemplary embodiment, a plurality of run clocks 142 at the DRPS 105 can track the amount of time each DRR 155 has been continuously on, or active, for the current session. In one exemplary embodiment, each run clock 142 is associated with the ID code 175 of a specific DRR 155 when the DRR 155 is initially turned on, or activated, so that the run clock 142 can track the amount of time the DRR 155 has been continuously on, or active, for the current session. In another exemplary embodiment, the DRR run clock 187 or the run clock 142 tracks the amount of time since an advertisement was transmitted to the DRR 155 or retrieved by the DRR 155 from its buffer in the hard drive and played for the listener. In another exemplary embodiment, the DRR run clock 187 or the run clock 142 tracks the amount of time since a particular advertisement was transmitted to the DRR 155. In this embodiment, multiple run clocks 187 or 142 would typically be required for each DRR 155.

The predetermined amount of time is used to control the frequency at which advertisements are played on the DRR 155. In another exemplary embodiment the system 100 uses the time of day to determine when advertisements are played on the DRR 155. For example, a signal to play an advertisement could be sent by the DRPS 105 at fifteen, thirty, and forty-five minutes past the hour and at the change of an hour (i.e. 6:15, 6:30, 6:45, and 7:00) or any other times during a day as selected by the provider of the system 100.

If the predetermined amount of time has not passed, the “NO” branch is followed to step 460, where the DRPS 105 continues transmitting the streaming signal for the selected radio feed to the DRR 155 or the DRR continues to retrieve the buffered feed from the hard drive for the DRR 155. The process then returns to step 455 and continues in a loop until the predetermined amount of time has passed. On the other hand, if the predetermined amount of time has passed, the “YES” branch is followed to step 465. In step 465, an inquiry is conducted to determine if the song or feed segment has concluded. The determination is typically conducted by the DRPS 105. In one exemplary embodiment, the DRPS 105 determines if a song has completed or a segment has ended for the selected radio feed in order that an advertisement is not transmitted during the middle of a song or segment. In another exemplary embodiment, segment breaks are inserted into the streaming signal of the selected radio feed or all radio feeds at once (called “blocking”) so that advertisements can be transmitted intermittently to the DRR 155. Through blocking, the automobile manufacturer can limit the ability of the listener to ad-skip by changing radio stations each time and ad is played by the DRR 155. The segment breaks can be inserted by the digital radio service provider or by the sponsor of a digital radio service that operates a DRPS 105.

If the song or segment has not concluded, the “NO” branch is followed back to step 465, which continues in a loop until the end of a song or segment is reached. Otherwise, the “YES” branch is followed to step 470, where an advertisement is retrieved from the advertisement database 135 and passed to the transmitter 115. In one exemplary embodiment, the advertisements retrieved from the advertisement database 135 can be the same or different from those advertisements previously retrieved at the conclusion of previous predetermined amounts of time and can be the same or different from the advertisement played when the DRR 155 is initially turned on, such as in step 440. In an alternative embodiment, the ad can be retrieved from the buffered database on the hard drive in the DRR 155 and played by the DRR 155. In step 475, the DRPS 105 transmits the retrieved advertisement to the DRR 155. In one exemplary embodiment, the DRPS 105 transmits the advertisement by passing it from the advertisement database 135 to the transmitter 115, to the antenna 110, and on to the DRR 155, by way of the satellite 195.

The DRR 155 receives the advertisement and plays the it on the DRR 155 in step 480. In one exemplary embodiment the DRR 155 receives the advertisement at the DRR antenna 185 and DRR receiver 165 and plays the advertisement by passing the advertisement from the DRR receiver 165 to one or more speakers 190. In step 485, the DRPS 105 transmits a streaming signal for the selected radio feed to the DRR 155. The streaming signal for the channel feed is typically retrieved from the channel feed supply 145 and passed to the transmitter 115 and antenna 110 for transmission to the DRR 155 by way of the satellite 195. In one exemplary embodiment, the DRPS 105 can pause the transmission of the streaming signal to the DRR 155 while the advertisement is played and can continue transmitting the streaming signal to the DRR 155 at the conclusion of the advertisement. In an alternative embodiment, the DRR 155 can pause the playing of the radio feed stored in the buffered database of the hard drive in the DRR 155 to play the ad and then continue retrieving the radio feed from the buffer and playing the buffered feed for the listener.

Returning to the exemplary embodiment, the DRR 155 receives the streaming signal for the selected radio feed and plays the streaming signal in step 490. In step 495, an inquiry is conducted to determine if the DRR 155 has been turned off. In one exemplary embodiment, determining whether the DRR 155 is turned off can be achieved by the DRR 155 transmitting a signal via the DRR transmitter 160 and DRR antenna 185 to the DRPS 105 or by the DRPS 105 pinging the DRR 155 via its transmitter 115 and antenna 110 and either not receiving a response back from the DRR 155 or receiving a response back from the DRR 155 at the receiver 120 through the antenna 110 that the DRR 155 has been turned off. If it is determined that the DRR 155 has not been turned off, the “NO” branch returns to step 455 to determine if the next predetermined amount of time has passed. Otherwise, the “YES” branch is followed to the END step.

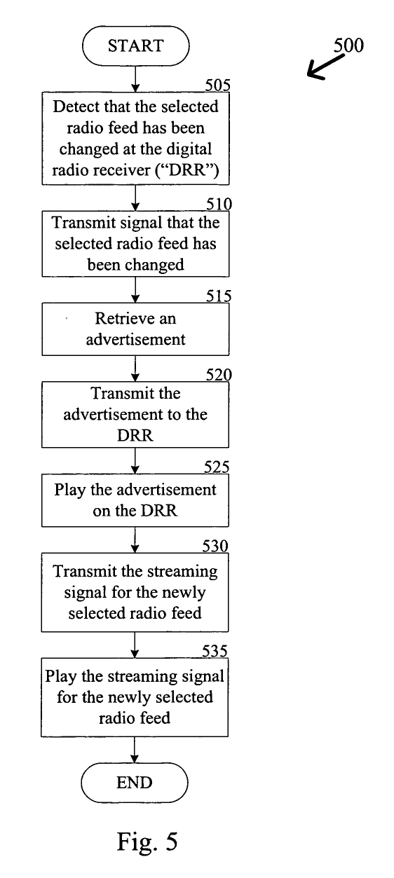

FIG. 5 is a logical flowchart diagram presented to illustrate the general steps of an exemplary process 500 for transmitting an advertisement to a DRR 155 upon the determination that the selected radio feed has been changed, within the operating environment of the exemplary transmission and receiving system 100 of FIG. 1. Referencing FIGS. 1 and 5, the exemplary method 500 begins at the START step and continues to step 505, where the DRR 155 detects that the selected radio feed has been changed. In one exemplary embodiment, the front panel display and switches 170 detects that the selected radio feed has been changed when a knob or switch for changing the radio feed on the front panel display and switches 170 is turned or depressed.

In step 510, a signal is transmitted that the selected radio feed has been changed. The signal is typically passed from the front panel display and switches 170 to the DRR transmitter 160 and transmitted through the DRR antenna 185 to the DRPS 105 via the satellite 195. In one exemplary embodiment, an ID code 175 can be transmitted with the signal to the DRPS 105. The signal can then be received by the antenna 110 and passed to the receiver 120. An advertisement is retrieved in step 515. The advertisement can be retrieved from the advertisement database 135. In one exemplary embodiment, the advertisement database 135 is capable of recording a listing of advertisements sent to a particular DRR 135 by associating the advertisement sent with the ID code 175 of the DRR 155. This embodiment can be used to limit the number of repeat advertisements or limit the amount of times a particular advertisement is transmitted to a specific DRR 155. In an alternative embodiment, the advertisement can be retrieved by the DRR 155 from the buffered database of ads on the hard drive of the DRR 155.

In step 520, the DRPS 105 transmits the retrieved advertisement to the DRR 155 by passing it from the advertisement database 135 to the transmitter 115, to the antenna 110, and on to the DRR 155, by way of the satellite 195. The DRR 155 receives the advertisement and plays it on the DRR 155 in step 525. In step 530, the DRPS 105 transmits a streaming signal for the newly selected radio feed to the DRR 155. The streaming signal for the newly selected radio feed is typically retrieved from the channel feed supply 145 and passed to the transmitter 115 and antenna 110 for transmission to the DRR 155 by way of the satellite 195. The DRR 155 receives the streaming signal for the selected radio feed and plays the streaming signal in step 535. In an alternative embodiment, the newly selected radio feed can be retrieved from the buffered database of radio feeds stored on the hard drive in the DRR 155 and played by the DRR 155. The process then continues to the END step.

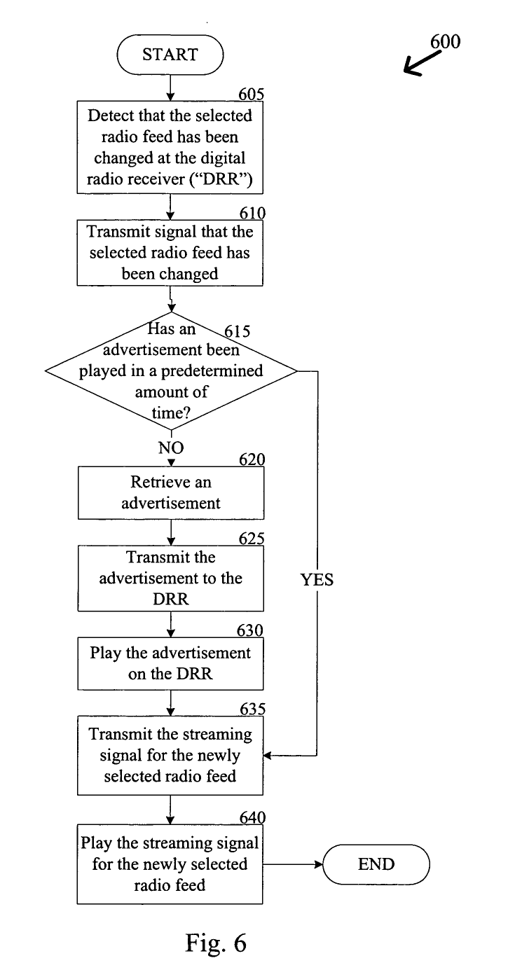

FIG. 6 is a logical flowchart diagram presented to illustrate the general steps of an alternate exemplary process 600 for transmitting an advertisement to a DRR 155 upon a determination that the selected radio feed has been changed, within the operating environment of the exemplary transmission and receiving system 100 of FIG. 1. Referencing FIGS. 1 and 6, the exemplary method 600 begins at the START step and continues to step 605, where the DRR 155 detects that the selected radio feed has been changed.

In step 610, a signal is transmitted that the selected radio feed has been changed. The signal is typically passed from the front panel display and switches 170 to the DRR transmitter 160 and transmitted through the DRR antenna 185 to the DRPS 105 via the satellite 195. In one exemplary embodiment, an ID code 175 can be transmitted with the signal to the DRPS 105. The signal can then be received by the antenna 110 and passed to the receiver 120. In step 615, an inquiry is conducted to determine if an advertisement has been played on the DRR 155 in a predetermined amount of time. The predetermined amount of time can be determined by evaluating the DRR run clock 187 or run clock 142.

In one exemplary embodiment, the DRR run clock 187 tracks the amount of time the DRR 155 has been continuously on, or active, for the current session. In another exemplary embodiment, a plurality of run clocks 142 at the DRPS 105 can track the amount of time each DRR 155 has been continuously on, or active, for the current session. In another exemplary embodiment, each run clock 142 is associated with the ID code 175 of a specific DRR 155 when the DRR 155 is initially turned on, or activated, so that the run clock 142 can track the amount of time the DRR 155 has been continuously on, or active, for the current session. In another exemplary embodiment, the DRR run clock 187 and/or the run clock 142 can track the amount of time since the last advertisement was transmitted to the DRR 155. In this exemplary embodiment, the determination of step 615 can be made by comparing the set predetermined amount of time to the amount of time since the last advertisement was transmitted to the DRR 155.

In another exemplary embodiment, when an advertisement is retrieved from the advertisement database 135, or from the buffered database in the hard drive for the DRR 155, it can record the identity of the advertisement, the ID code 175 of the DRR 155 and the time that the advertisement was transmitted. In this exemplary embodiment, the determination of step 615 can be accomplished by comparing the set predetermined amount of time to the difference in current time and the time that an advertisement was last transmitted to the DRR 155 having the received ID code 175.

If an advertisement has not been played in a predetermined amount of time, the “NO” branch is followed to step 620. Otherwise, the “YES” branch is followed to step 635. In step 620, an advertisement is retrieved from the advertisement database 135. In one exemplary embodiment, the advertisement database 135 is capable of recording a listing of advertisements sent to a particular DRR 135 by associating the advertisement sent with the ID code 175 of the DRR 155. This embodiment can be used to limit the number of repeat advertisements or limit the amount of times a particular advertisement is transmitted to a specific DRR 155.

In step 625, the DRPS 105 transmits the retrieved advertisement to the DRR 155 by passing it from the advertisement database 135 to the transmitter 115, to the antenna 110, and on to the DRR 155, by way of the satellite 195. The DRR 155 receives the advertisement and plays the it on the DRR 155 in step 630. In step 635, the DRPS 105 transmits a streaming signal for the newly selected radio feed to the DRR 155. The streaming signal for the newly selected channel feed is typically retrieved from the channel feed supply 145 and passed to the transmitter 115 and antenna 110 for transmission to the DRR 155 by way of the satellite 195. The DRR 155 receives the streaming signal for the selected radio feed and plays the streaming signal in step 640. In another exemplary embodiment, the streaming signal is retrieved from the stored buffer in the hard drive of the DRR 155 by the DRR 155 and played for the listener. The process then continues to the END step.

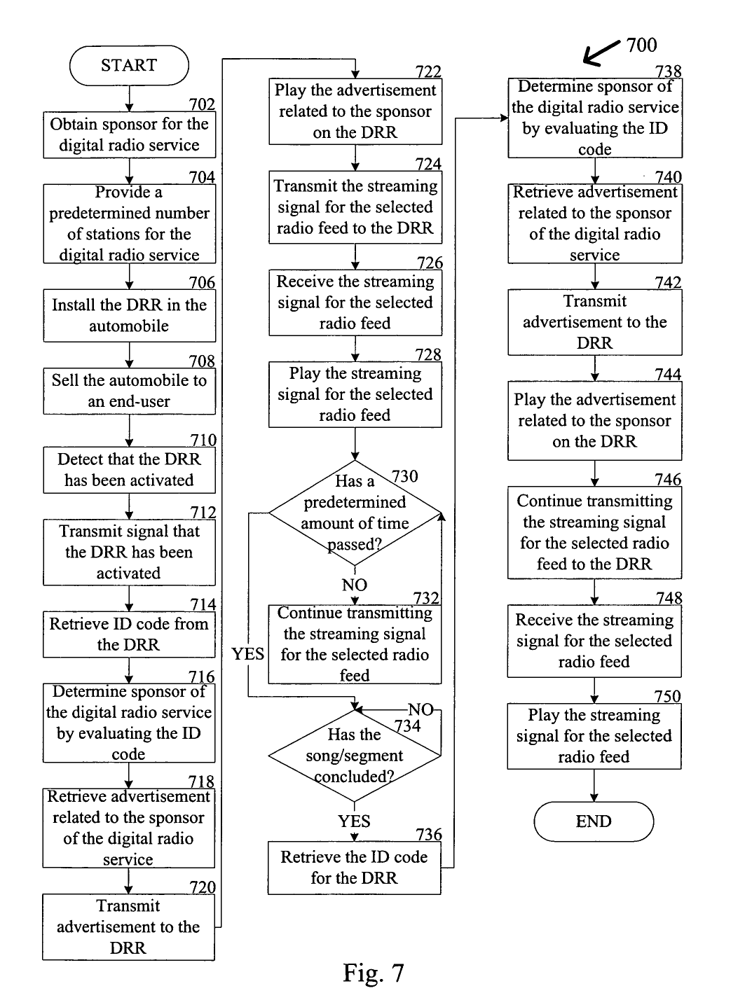

FIG. 7 is a logical flowchart diagram presented to illustrate the general steps of an exemplary process 700 for obtaining sponsorship for a digital radio service and providing targeted advertising related to the sponsor, within the operating environment of the exemplary transmission and receiving system 100 of FIG. 1. Referencing FIGS. 1 and 7, the exemplary method 700 begins at the START step and continues to step 702, where a sponsor is obtained for the digital radio service 100. In one exemplary embodiment, the sponsor is obtained by the automobile dealership that is selling the automobile 150 in order to subsidize or fully cover the cost of the digital radio service 100, including the DRR 155. The sponsor can be the manufacturer of the automobile 150, a large national retail company, a local franchise or affiliate of a large retail company, or a retail company that is in the same locale as the automobile dealership. In step 704, a predetermined number of digital channel feeds are programmed into the DRR 155. The DRR 155 is installed in the automobile 150 in step 706. In step 708, the automobile 150 containing the DRR 155 is sold to a consumer. The DRR 155 detects that it has been turned on in step 710.

In step 712, the DRR 155 transmits a signal to the DRPS 105 that the DRR 155 has been turned on. The DRR 155 typically transmits this information by sending a signal from the DRR transmitter 160 through the DRR antenna 185 to the antenna 110, by way of the satellite 195. In step 714, the ID code 175 is accepted from the DRR 155 at the DRPS 105. In step 716, the DRPS 105 determines the sponsor of the digital radio service 100 for the DRR 155. In one exemplary embodiment, the advertisement database 135, the consumer preferences and demographics database 125, or some other database in the DRPS 105 can include a table that provides a listing of ID codes 175 and the sponsor of the service for the DRR 155 having the particular ID code 175. In step 718, the DRPS 105 retrieves an advertisement from the advertisement database 135 for the sponsor of the digital radio service 100 based on the determination made in step 716. The advertisement for the sponsor can include, but is not limited to, an advertisement to buy a product or products offered or manufactured by the sponsor, a news bulletin sponsored by the sponsor of the digital radio service 100, or other information that may be of interest to the occupants of the automobile 150.

In step 720, the DRPS 105 transmits the retrieved advertisement to the DRR 155 by passing it from the advertisement database 135 to the transmitter 115, to the antenna 110, and on to the DRR 155, by way of the satellite 195. The DRR 155 receives the advertisement related to the sponsor and plays the it on the DRR 155 in step 722 by receiving the advertisement at the DRR antenna 185 and DRR receiver 165 and playing the advertisement on one or more speakers 190. In step 724, the DRPS 105 transmits a streaming signal for the selected radio feed to the DRR 155. The streaming signal for the channel feed is typically retrieved from the channel feed supply 145 and passed to the transmitter 115 and antenna 110 for transmission to the DRR 155 by way of the satellite 195.

The DRR 155 receives the streaming signal for the selected radio feed at the DRR receiver 165 through the DRR antenna 185 in step 726. In step 728, the DRR 155 plays the streaming signal for the selected radio feed on one or more speakers 190. An inquiry is conducted in step 730 to determine if a predetermined amount of time has passed. The predetermined amount of time is used to control the frequency at which advertisements are played on the DRR 155. The predetermined amount of time can be any amount from zero seconds to an infinite amount of minutes. In one exemplary embodiment, the predetermined amount of time is ten, twenty and thirty minutes.

The predetermined amount of time can be determined by evaluating the DRR run clock 187 or run clock 142. In one exemplary embodiment, the DRR run clock 187 tracks the amount of time the DRR 155 has been continuously on, or active, for the current session. In another exemplary embodiment, a plurality of run clocks 142 at the DRPS 105 can track the amount of time each DRR 155 has been continuously on, or active, for the current session. In another exemplary embodiment, each run clock 142 is associated with the ID code 175 of a specific DRR 155 when the DRR 155 is initially turned on, or activated, so that the run clock 142 can track the amount of time the DRR 155 has been continuously on, or active, for the current session.

In another exemplary embodiment, a table in the advertisement database 135, consumer preferences and demographics database 125, or some other database in the DRPS 105 or DRR 155 records the time of each advertisement transmitted to a DRR 155 and the ID code 175. In this embodiment, the amount of time since the last advertisement was sent to the DRR 155 having a particular ID code 175 can be determined by subtracting the last entry in the table from the current time. In this embodiment, the table can also include a listing or code denoting which advertisement was transmitted to the DRR 155 so that the same advertisement will not be repeated at too frequent a rate and so that a variety of advertisements and information is transmitted to the DRR 155.

In another exemplary embodiment the system 100 uses the time of day to determine when advertisements are played on the DRR 155. For example, a signal to play an advertisement could be sent by the DRPS 105 at fifteen, thirty, and forty-five minutes past the hour and at the change of an hour (i.e. 6:15, 6:30, 6:45, and 7:00) or any other time during a day as selected by the provider of the system 100.

If the predetermined amount of time has not passed, the “NO” branch is followed to step 732, where the DRPS 105 continues transmitting the streaming signal for the selected radio feed to the DRR 155 or the DRR 155 continues to retrieve the buffered feed from the hard drive in the DRR 155. The process then returns to step 730 and continues in a loop until the predetermined amount of time has passed. On the other hand, if the predetermined amount of time has passed, the “YES” branch is followed to step 734. In step 734, an inquiry is conducted to determine if the song or feed segment has concluded. The determination is typically conducted by the DRPS 105. In one exemplary embodiment, the DRPS 105 determines if a song has completed or a segment has ended for the selected radio feed so that an advertisement is not transmitted during the middle of a song or segment.

If the song or segment has not concluded, the “NO” branch is followed back to step 734, which continues in a loop until the end of a song or segment is reached. Otherwise, the “YES” branch is followed to step 736, where the ID code 175 is accepted by the DRPS 105 from the DRR 155. In step 738, the sponsor of the digital radio service 100 is determined by evaluating the ID code in a process similar to that of step 716. In step 740, an advertisement related to the sponsor of the digital radio service 100 is retrieved from the advertisement database 135 and passed to the transmitter 115. In one exemplary embodiment, the advertisements retrieved from the advertisement database 135 or stored in a buffer in the hard drive for the DRR 155 can be the same or different from those advertisements previously retrieved at the conclusion of previous predetermined amount of time and can be the same or different from the advertisement played when the DRR 155 is initially turned on, such as in step 722.

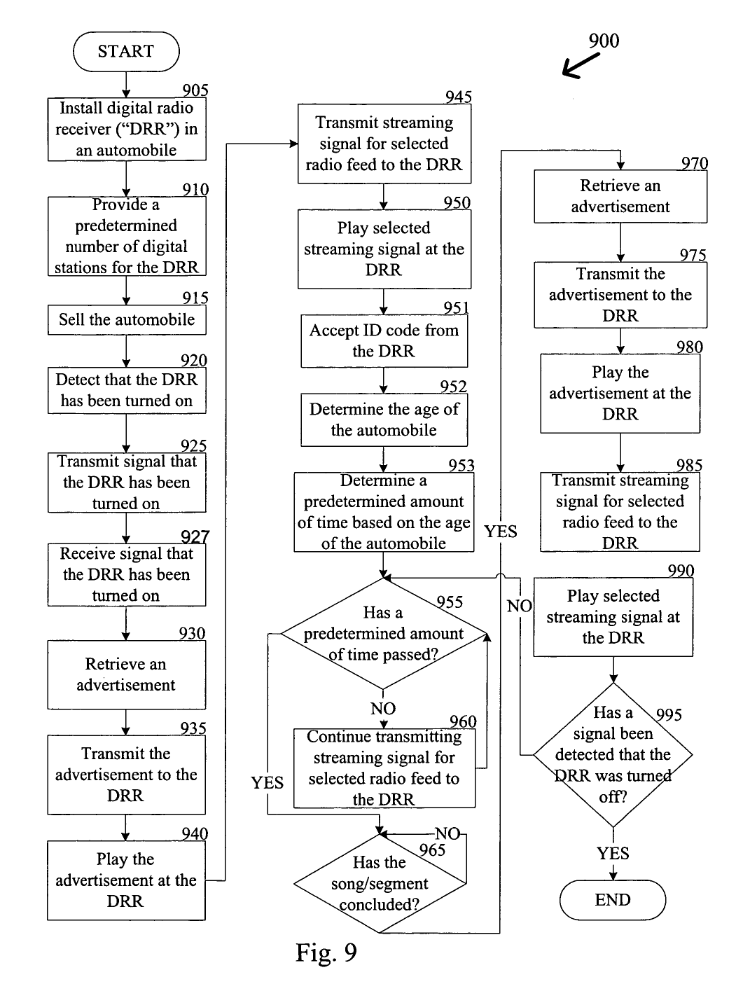

In step 742, the DRPS 105 transmits the retrieved advertisement to the DRR 155. The DRR 155 receives the advertisement and plays it on the DRR 155 in step 744. In an alternative embodiment, the DRR 155 retrieves the advertisement from the buffer in the hard drive in the DRR 155. In step 746, the DRPS 105 transmits a streaming signal for the selected radio feed to the DRR 155. The streaming signal for the channel feed is typically retrieved from the channel feed supply 145 and passed to the transmitter 115 and antenna 110 for transmission to the DRR 155 by way of the satellite 195. The DRR 155 receives the streaming signal for the selected radio feed in step 748. In step 750, the DRR 155 plays the streaming signal. The process is then followed to the END step. Those of ordinary skill in the art will understand that the invention of FIG. 7 could be combined with the invention of FIG. 4 so as to loop the advertisement monitoring system until the DRR 155 is turned off. Those ordinary skill in the art will also understand that the invention of FIG. 7 could be combined with the invention of FIG. 5 or 6 in order to play an advertisement related to the sponsor of the digital radio service 100 when a change in the selected radio feed is detected. Those of ordinary skill in the art will further understand that the invention of FIG. 7 could be combined with the invention of FIG. 9 in order to increase the frequency of an advertisement related to the sponsor as the age of the consumer or the automobile 150 increases.

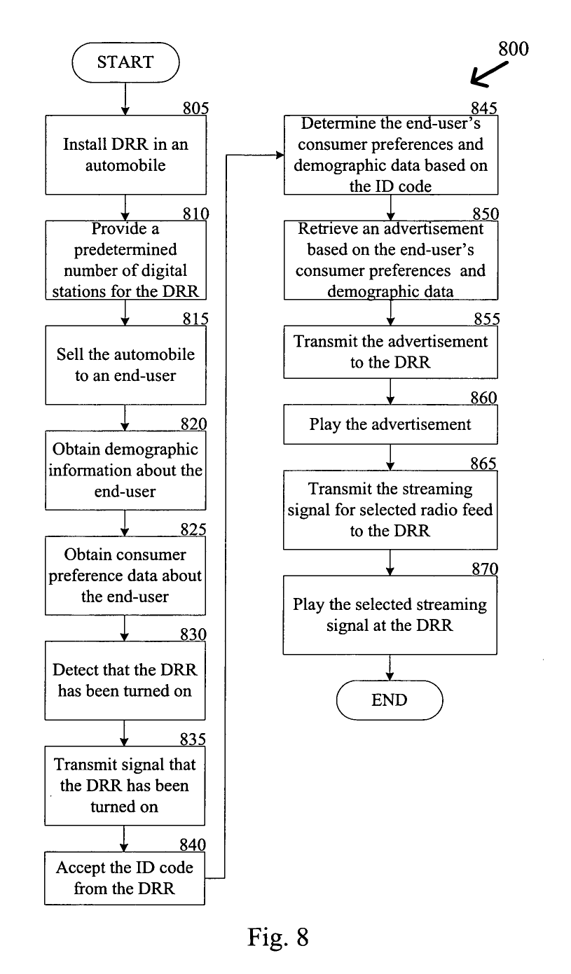

FIG. 8 is a logical flowchart diagram presented to illustrate the general steps of an exemplary process 800 for obtaining and transmitting targeted advertising to a DRR 155 based on the consumer preferences or demographic information of the owner of the automobile 150 in which the DRR 155 is installed, within the operating environment of the exemplary transmission and receiving system 100 of FIG. 1. Referencing FIGS. 1 and 8, the exemplary method 800 begins at the START step and continues to step 805, where the DRR 155 in installed in an automobile 150. In step 810, a predetermined number of digital channel feeds are programmed into or provided for the DRR 155. The digital channel feeds are typically programmed into the DRR receiver 165. The predetermined number of channel feeds can be any number greater than zero, however, the number of channel feeds can be limited by the total amount of bandwidth available to the digital radio service provider. In one exemplary embodiment, the automobile manufacture secures a number of digital channel feeds from a digital radio service provider that are separate from the digital radio feeds provided to subscribers to the digital radio service provider. In one exemplary embodiment, the separate digital radio feeds can be transmitted only to DRRs 155 that are installed in the manufacturer's automobiles 150.

In step 815, the automobile 150 containing the DRR 155 is sold to a consumer. The automobile 150 is typically sold to the consumer at an automobile dealership. Demographic information about the consumer who purchased the automobile is obtained in step 820. The demographic information can be obtained by directly requesting this information from the consumer or by obtaining the demographic information from a third party based on basic information provided by the consumer, such as name and address. In one exemplary embodiment, demographic information can include, race, age, political affiliation, median income, and family demographics.

In step 825, consumer preference data related to the consumer is obtained. Consumer preference data can be obtained by directly requesting this information from the consumer at the time of purchase at a dealership, through surveys that are mailed to the consumer after the purchase of the automobile 150, through on-line or telephonic surveys of the consumer after the purchase of the automobile 150, or by obtaining the consumer preference information from a third party based on basic information provided by the consumer at the time of purchase. Consumer preference information can include, but is not limited to, preferences of the consumer or their family related to models of automobiles, clothing, music preferences, cell phone and other technology preferences, and retail store preferences. The information obtained in steps 820 and 825 can be stored in the consumer preferences and demographics database 125, which can be located in the DRPS 105 or the DRR 155 (Not Shown). Those of ordinary skill in the art will understand that the invention could operate in a similar fashion by obtaining either the demographic information or the consumer preference information or both types of information.

The DRR 155 detects that it has been turned on, or activated, in step 830. In one exemplary embodiment, the DRR 155 detects that it has been turned on when an occupant in the automobile 150 turns a power knob or pushes a power button on the front panel display and switches 170. In step 835, the DRR 155 transmits a signal that the DRR 155 has been turned on. The DRR typically transmits this information by sending a signal from the DRR transmitter 160 through the DRR antenna 185 to the antenna 110, by way of the satellite 195. The DRPS 105 then receives the signal that the DRR 155 has been turned on through the antenna 110 to the receiver 120. In step 840, the DRPS 105 accepts the ID code 175 from the DRR 155. The ID code is typically transmitted from the DRR transmitter 160 through the DRR antenna 185 to the DRPS 105, by way of the satellite 195, through the antenna 110 and receiver 120.

The consumer's consumer preferences and demographics can be evaluated based on the accepted ID code 175 in step 845. In one exemplary embodiment, the ID code 175 is compared to a table of ID codes 175 in the consumer preferences and demographics database 125. The ID code 175 in the consumer preferences and demographics database 125 that matches the accepted ID code 175, will provide a table of preferences and demographics for the consumer of that automobile 150. Based on the preferences and demographics of the particular consumer, targeted advertisements can be retrieved from the advertisement database 135 in step 850. In one exemplary embodiment, the advertisement database 135 or the consumer preferences and demographics database 125 could also contain a listing by ID code 175 of the previous advertisements sent to a particular DRR 155, in order to limit the repetitiveness of the advertisements transmitted to a particular DRR 155.

In step 855, the DRPS 105 transmits the retrieved advertisement to the DRR 155 by passing it from the advertisement database 135 to the transmitter 115, to the antenna 110, and on to the DRR 155, by way of the satellite 195. In an alternative embodiment, the advertisements and radio feeds can be buffered in the hard drive of the DRR 155 and played at a subsequent time. The DRR 155 receives the advertisement and plays it on the DRR 155 in step 860 by receiving the advertisement at the DRR antenna 185 and DRR receiver 165 and playing the advertisement by passing the advertisement from the DRR receiver 165 to one or more speakers 190. In step 865, the DRPS 105 transmits a streaming signal for the selected radio feed to the DRR 155. The streaming signal for the radio feed is typically retrieved from the channel feed supply 145 and passed to the transmitter 115 and antenna 110 for transmission to the DRR 155 by way of the satellite 195. In an alternative embodiment, the radio feed is retrieved by the DRR 155 from the buffer in the hard drive for the DRR 155 and played for the listener.

Returning to the exemplary embodiment, the DRR 155 receives the streaming signal for the selected radio feed and plays the streaming signal in step 870 by receiving the streaming signal at the DRR antenna 185 and passing the signal to the DRR receiver 165, which begins playing the received streaming signal for the selected radio feed by passing the signal from the DRR receiver 165 to one or more speakers 190. The process then continues to the END step. Those of ordinary skill in the art will understand that the invention described in FIG. 8 could be combined with the invention described in FIG. 4 in order to play multiple advertisements during predetermined periods of time. Those of ordinary skill in the art will also understand that the invention described in FIG. 8 could also be combined with the inventions described in FIG. 4 or 5 in order to play targeted advertisements based on the consumers demographics or preferences each time the DRR 155 detects that the selected radio feed has been changed.

FIG. 9 is a logical flowchart diagram presented to illustrate the general steps of an exemplary process 900 for modifying the rate of targeted advertising transmitted to a DRR 155 based on the age of the automobile 150 in which the DRR 155 is installed, within the operating environment of the exemplary transmission and receiving system 100 of FIG. 1. Referencing FIGS. 1 and 9, the exemplary method 900 begins at the START step and continues to step 905, where the DRR 155 is installed in an automobile 150. In step 910, a predetermined number of digital channel feeds are programmed into the DRR 155. In step 915, the automobile 150 containing the DRR 155 is sold to a consumer. The DRR 155 detects that it has been turned on in step 920.

In step 925, the DRR 155 transmits a signal that the DRR 155 has been turned on. The DRR 155 typically transmits this information by sending a signal from the DRR transmitter 160 through the DRR antenna 185 to the antenna 110, by way of the satellite 195. The DRPS 105 receives the signal that the DRR 155 has been turned on through the antenna 110 to the receiver 120 in step 927. In step 930, the DRPS 105 retrieves an advertisement from the advertisement database 135 for the automobile's manufacturer. The advertisement for the automobile's manufacture can include, but is not limited to, an advertisement to buy an automobile manufactured by the same manufacturer, a news bulletin sponsored by the manufacturer of the automobile 150, or other information that may be of interest to the occupants of the automobile 150.

In step 935, the DRPS 105 transmits the retrieved advertisement to the DRR 155 by passing it from the advertisement database 135 to the transmitter 115, to the antenna 110, and on to the DRR 155, by way of the satellite 195. The DRR 155 receives the advertisement and plays the it on the DRR 155 in step 940 by receiving the advertisement at the DRR antenna 185 and DRR receiver 165 and playing the advertisement on one or more speakers 190. In step 945, the DRPS 105 transmits a streaming signal for the selected radio feed to the DRR 155. The streaming signal for the channel feed is typically retrieved from the channel feed supply 145 and passed to the transmitter 115 and antenna 110 for transmission to the DRR 155 by way of the satellite 195.

The DRR 155 receives the streaming signal for the selected radio feed at the DRR receiver 165 and plays the streaming signal on one or more speakers 190 in step 950. In step 951, the DRPS accepts the ID code 175 from the DRR 155. The age or model year of the automobile is determined in step 952. In one exemplary embodiment, the advertisement database 135, the consumer preferences and demographics database 125, or some other database in the DRPS 105 or the DRR 155 can store a table having the ID code 175 and the age or model year of the automobile 150. If the model year is included in the table, the age of the vehicle can typically be determined by subtracting the model year from the current calendar year, or in the alternative, the current model year. In step 953, a determination is made as to whether a predetermined amount of time has passed based on the age of the automobile 150. In one exemplary embodiment, the age of the automobile can be compared to a table in the advertisement database 135, the consumer preferences and demographics database 125, or some other database in the DRPS 105 or DRR 155. The table will typically include the age of the automobile 150 and the predetermined amount of time between advertisements for a new automobile from the manufacturer. Typically, the predetermined amount of time between advertisements for the purchase of a new or used automobile from the manufacturer will decrease as the automobile 150 gets older.

An inquiry is conducted in step 955 to determine if a predetermined amount of time has passed. The predetermined amount of time can be any amount from zero seconds to an infinite amount of minutes. The predetermined amount of time can be determined by evaluating the DRR run clock 187 or run clock 142. In one exemplary embodiment, the DRR run clock 187 tracks the amount of time the DRR 155 has been continuously on, or active, for the current session. In another exemplary embodiment, a plurality of run clocks 142 at the DRPS 105 can track the amount of time each DRR 155 has been continuously on, or active, for the current session. In another exemplary embodiment the system 100 uses the time of day to determine when advertisements are played on the DRR 155. For example, a signal to play an advertisement could be sent by the DRPS 105 at fifteen, thirty, and forty-five minutes past the hour and at the change of an hour (i.e. 6:15, 6:30, 6:45, and 7:00) or any other time during a day, as selected by the provider of the system 100. In another exemplary embodiment, each run clock 142 is associated with the ID code 175 of a specific DRR 155 when the DRR 155 is initially turned on, or activated, so that the run clock 142 can track the amount of time the DRR 155 has been continuously on, or active, for the current session. In another exemplary embodiment, each run clock 142 is associated with the ID code 175 of a specific DRR 155, when the DRR 155 is initially turned on, and the run clock 142 tracks the amount of time since the last advertisement for a new automobile was transmitted to that DRR 155. In another exemplary embodiment a table can be created in the advertisement database 135, the consumer preferences and demographics database 125, or some other database in the DRPS 105 or DRR 155 that contains the ID code 175 and the time the last advertisement for a new automobile was transmitted to that DRR 155. The amount of time between advertisements could then be calculated by subtracting the time provided in the table from the current time.

If the predetermined amount of time has not passed, the “NO” branch is followed to step 960, where the DRPS 105 continues transmitting the streaming signal for the selected radio feed to the DRR 155. The process then returns to step 955 and continues in a loop until the predetermined amount of time has passed. On the other hand, if the predetermined amount of time has passed, the “YES” branch is followed to step 965. In step 965, an inquiry is conducted to determine if the song or feed segment has concluded. The determination is typically conducted by the DRPS 105. If the song or segment has not concluded, the “NO” branch is followed back to step 965, which continues in a loop until the end of a song or segment is reached. Otherwise, the “YES” branch is followed to step 970, where an advertisement for the purchase of a new automobile from the manufacturer of the automobile 150 is retrieved from the advertisement database 135 and passed to the transmitter 115. In one exemplary embodiment, the advertisements retrieved from the advertisement database 135 can be the same or different from those advertisements previously retrieved at the conclusion of previous predetermined amounts of time and can be the same or different from the advertisement played when the DRR 155 is initially turned on, such as in step 940. In step 975, the DRPS 105 transmits the retrieved advertisement to the DRR 155.

The DRR 155 receives the advertisement and plays it on the DRR 155 in step 980. In step 985, the DRPS 105 transmits a streaming signal for the selected radio feed to the DRR 155. The DRR 155 receives the streaming signal for the selected radio feed and plays the streaming signal in step 990. In step 995, an inquiry is conducted to determine if the DRR 155 has been turned off. In one exemplary embodiment determining whether the DRR 155 is turned off can be achieved by the DRR 155 transmitting a signal via the DRR transmitter 160 and DRR antenna 185 to the DRPS 105 or by the DRPS 105 pinging the DRR 155 via its transmitter 115 and antenna 110 and either not receiving a response back from the DRR 155 or receiving a response back from the DRR 155 at the receiver 120 through the antenna 110 that the DRR 155 has been turned off. If it is determined that the DRR 155 has not been turned off, the “NO” branch returns to step 955 to determine if the next predetermined amount of time has passed. Otherwise, the “YES” branch is followed to the END step.

In another exemplary embodiment, an automobile manufacturer could enter into an agreement with a digital satellite or Internet service provider. As part of this agreement, the service provider would stream about multiple types of radio station genres to cars manufactured by the automobile manufacturer. Also, as part of the agreement, the cost of the receiver units can be all or partially subsidized by the automobile manufacture and/or the service provider. While the radio feeds would be national, the service provider could insert breaks within the national content that would allow for local insertion of local news, weather, traffic information, and ads controlled by the automobile manufacturer. The service provider would even have the capability to block the breaks for each channel feed so that they occur at the same time. By blocking the breaks, the automobile manufacturer can deliver its local information and ads from a single local provider, selected by the automobile manufacturer. Furthermore, by blocking the breaks for all of the channel feeds at the same time, the occupants of the automobile 150 will have a more difficult time ad-skipping by switching channel feeds, since each feed will be playing the same local information, including local advertisements, at the same time.

In another exemplary embodiment, an automobile manufacturer could enter into an agreement with a digital satellite or Internet service provider. As part of this agreement, the service provider would stream several types of radio station genres on an ad-free basis to cars manufactured by the automobile manufacturer. While not playing conventional advertisements, disc jockeys for each radio genre could provide additional advertising value for the automobile manufacturer by “plugging” the automobile manufacturer or reminding the listener that the free digital radio and ad free content that they are listening to was brought to them by the automobile manufacturer. For example, the disc jockey could say, “you're listening to XYZ (name of the automobile manufacturer) radio, maker's of the new FLASH model featuring xenon lights and Freon-free air conditioning and starting at a price of $19,900.”

While not having the ability to provide standard advertisements, the exemplary method, at a minimum, eliminates a competing automobile manufacturer from being able to broadcast advertisements in the automobile while still allowing the automobile manufacturer to provide its advertising messages through the disc jockey's comments. Such an exemplary method locks the competition out of the advertising space within the automobile, while providing the automobile manufacturer the capability of being the sole advertiser in the automobile for as long as the automobile is in use. The exemplary method allows an automobile manufacturer to spend approximately four hundred dollars per car in advertising (for the cost of the DRR 155) while reducing the automobile manufacturer's costs elsewhere by having a more focused advertising audience. The subsequent reduction in advertising expenditures can then be put towards subsidizing the installation of the DRR equipment and broadcast fees.

In conclusion, the present invention supports a method for transmitting targeted advertising from the manufacturer of an automobile to a digital radio receiver installed in an automobile manufactured by the manufacturer. Furthermore, the present invention supports a method for increasing the amount of targeted advertising from the manufacturer to a digital radio receiver installed in an automobile as the automobile ages. The present invention further supports a method obtaining demographic and consumer preference information for the purchaser of an automobile having a digital radio receiver and transmitting targeted advertising based on the demographic and consumer preference information. The present invention further supports a method for obtaining sponsorship for a digital radio service and providing targeted advertising related to the sponsor to the digital radio receivers subsidized by the sponsor. The present invention further supports a method for providing a digital radio receiver and a plurality of channel feeds in an automobile without commercial interruption by an automobile manufacturer and presenting the occupants in the automobile with periodic reminders by a disc jockey or other voice over that the commercial free radio is provided by the automobile manufacturer and presenting information about products provided by the automobile manufacturer. It will be appreciated that the present invention fulfills the needs of the prior art described herein and meets the above-stated objectives. While there have been shown and described several exemplary embodiments of the present invention, it will be evident to those skilled in the art that various modifications and changes can be made thereto without departing from the spirit and the scope of the present invention as set forth in the appended claims and equivalence thereof.

I claim:

1. A method for providing targeted advertising to a digital radio receiver installed in an automobile comprising:
providing a digital radio receiver that can only receive advertisements sponsored by a manufacturer of the automobile;
receiving a first signal that the digital radio receiver has been activated at a digital radio provider service;
accepting a first advertisement sponsored by the manufacturer of the automobile at the digital radio receiver;
playing the first advertisement at the digital radio receiver;
accepting a first streaming signal for a first selected radio feed at the digital radio receiver; and
playing the first streaming signal at the digital radio receiver.

2. The method of claim 1, wherein the cost of the digital radio receiver, a digital radio service, and installation of the digital radio receiver into the automobile is subsidized by the manufacturer of the automobile.

3. The method of claim 1, wherein the digital radio receiver is installed in the automobile.

4. The method of claim 1, further comprising the steps of:
determining if a first predetermined amount of time has passed since the first streaming signal was accepted at the digital radio receiver;
if the first predetermined amount of time has passed, accepting a second advertisement sponsored by the manufacturer of the automobile at the digital radio receiver;
playing the second advertisement at the digital radio receiver;
accepting the first streaming signal for the first selected radio feed at the digital radio receiver; and
playing the first streaming signal at the digital radio receiver.

5. The method of claim 4, further comprising the steps of:
if the first predetermined amount of time has passed, determining if a first segment of the first streaming signal has reached a conclusion;
if the first segment of the first streaming signal has reached a conclusion, accepting the second advertisement sponsored by the manufacturer of the automobile at the digital radio receiver;
playing the second advertisement at the digital radio receiver;
accepting the first streaming signal for the first selected radio feed at the digital radio receiver;
playing the first streaming signal at the digital radio receiver; and
if the first segment of the first streaming signal has not reached a conclusion, continue playing the first streaming signal at the digital radio receiver.

6. The method of claim 4, further comprising the steps of:
determining if the digital radio receiver has been deactivated;
if the digital radio receiver has not been deactivated, determining if a second predetermined amount of time has passed since the second advertisement was played at the digital radio receiver;
if the second predetermined amount of time has passed, accepting a third advertisement sponsored by the manufacturer of the automobile at the digital radio receiver;
playing the third advertisement at the digital radio receiver;
accepting the first streaming signal for the first selected radio feed at the digital radio receiver; and
playing the first streaming signal at the digital radio receiver.

7. The method of claim 1, further comprising the steps of:
accepting an input for a second selected radio feed;
accepting a signal that the radio feed has been changed from the first selected radio feed to the second selected radio feed;
accepting a fourth advertisement sponsored by the manufacturer of the automobile at the digital radio receiver;
playing the fourth advertisement at the digital radio receiver;
accepting a second streaming signal for the second selected radio feed at the digital radio receiver; and
playing the second streaming signal at the digital radio receiver.

8. The method of claim 1, further comprising the steps of:
accepting an input for a second selected radio feed;
accepting a signal that the radio feed has been changed from the first selected radio feed to the second selected radio feed;
determining if a predetermined amount of time has passed since an advertisement has played on the digital radio receiver;
if the predetermined amount of time has not passed, accepting a second streaming signal for the second selected radio feed at the digital radio receiver; and
playing the second streaming signal at the digital radio receiver.

9. The method of claim 8, further comprising the steps of:
if the predetermined amount of time has passed, accepting a fourth advertisement sponsored by the manufacturer of the automobile at the digital radio receiver;
playing the fourth advertisement at the digital radio receiver;
accepting the second streaming signal for the second selected radio feed at the digital radio receiver; and
playing the second streaming signal at the digital radio receiver.

10. A method for providing targeted advertising related to a sponsor of a digital radio service to a digital radio receiver installed in an automobile comprising:
obtaining a local sponsor for the digital radio service, whereby the local sponsor subsidizes the cost of the digital radio receiver, the digital radio service, and installation of the digital radio receiver into the automobile;
providing the digital radio receiver installed in the automobile, whereby the digital radio receiver can only receive advertisements sponsored by the local sponsor;
selling the automobile with the digital radio receiver installed to an end-user;
accepting a first streaming signal for a first selected radio feed from the digital radio provider service at the digital radio receiver;
playing the first streaming signal at the digital radio receiver;
determining if a predetermined amount of time has passed since the first streaming signal was accepted at the digital radio receiver;
if the first predetermined amount of time has passed, pausing the first selected radio feed;
accepting a first advertisement sponsored by the local sponsor at the digital radio receiver;
playing the first advertisement at the digital radio receiver; and
continue playing the first streaming signal for the first selected radio feed at the digital radio receiver.

11. The method of claim 10, further comprising the steps of:
receiving a signal that the digital radio receiver has been activated at a digital radio provider service;
accepting a second advertisement sponsored by the local sponsor at the digital radio receiver;
playing the second advertisement at the digital radio receiver;
accepting the first streaming signal for a first selected radio feed from the digital radio provider service at the digital radio receiver; and
playing the first streaming signal at the digital radio receiver.

12. The method of claim 10, further comprising the steps of:
accepting an identification code for the digital radio receiver, wherein the identification code can be used to identify the local sponsor for the digital radio service;
evaluating the identification code to determine the local sponsor of the digital radio service;
accepting the first advertisement related to the local sponsor based on the evaluation of the identification code; and
playing the first advertisement on the digital radio receiver.

13. The method of claim 12, wherein the identification code is unique for each digital radio receiver.

14. The method of claim 10, further comprising the steps of:
a. determining if a first segment of the first streaming signal has reached a conclusion if the first predetermined amount of time has passed;
b. playing the first streaming signal at the digital radio receiver if the first segment of the first streaming signal has not reached a conclusion;
c. continuing steps (a)-(b) until the first segment of the first streaming signal reaches a conclusion; and
d. accepting the first advertisement sponsored by the local sponsor at the digital radio receiver if the first segment of the first streaming signal has reached a conclusion.

15. The method of claim 14, wherein the first segment concludes at the end of a song.

16. The method of claim 10, further comprising the steps of:
accepting an input for a second selected radio feed at the digital radio receiver;
accepting a signal that the radio feed has been changed from the first selected radio feed to the second selected radio feed;
accepting an identification code for the digital radio receiver, wherein the identification code can be evaluated to determine the local sponsor for the digital radio service;
accepting a third advertisement sponsored by the local sponsor based on an evaluation of the identification code;
playing the third advertisement at the digital radio receiver;
accepting a second streaming signal for the second selected radio feed at the digital radio receiver; and
playing the second streaming signal at the digital radio receiver.

17. A method for providing targeted advertising to a consumer through a digital radio receiver installed in an automobile comprising:
obtaining a plurality of sponsors for a digital radio service; whereby the sponsors subsidize the cost of the digital radio receiver, the digital radio service, and installation of the digital radio receiver into the automobile;
providing the digital radio receiver installed in the automobile, whereby the digital radio receiver can only receive advertisements sponsored by the plurality of sponsors;
selling the automobile with the installed digital radio receiver to an end-user;
obtaining information about the end-user;
associating the information about the end-user with an identification code for the digital radio receiver, wherein the identification code is unique for each of a plurality of digital radio receivers;
accepting a first signal that the digital radio receiver has been activated at a digital radio provider service;
accepting the identification code for the digital radio receiver;
evaluating the information about the end-user associated with the identification code to determine at least one sponsor having a product that may be of interest to the end-user;
retrieving a first advertisement related to a sponsor having a product that may be of interest to the end-user based on identification code and the associated information;
playing the first advertisement at the digital radio receiver;
accepting a first streaming signal for a first selected radio feed at the digital radio receiver; and
playing the first streaming signal at the digital radio receiver.

18. The method of claim 17, wherein the information about the end-user comprises demographic information about the end-user.

19. The method of claim 17, wherein the information about the end-user comprises consumer preference information.

20. The method of claim 17, further comprising the steps of:
determining if a first predetermined amount of time has passed since the first streaming signal was accepted at the digital radio receiver;
accepting the identification code for the digital receiver if the first predetermined amount of time has passed;
evaluating the information about the end-user associated with the identification code to determine at least one sponsor having a product that may be of interest to the end user;
pausing a transmission of the first streaming signal for the first selected radio feed;
accepting a second advertisement related to the sponsor having a product that may be of interest to the end-user;
playing the second advertisement at the digital radio receiver; and
resuming the transmission of the first streaming signal for the first selected radio feed to the digital radio receiver.

21. The method of claim 20, wherein the sponsor for the first advertisement and the sponsor for the second advertisement are different.

22. The method of claim 20, wherein determining the first predetermined amount of time comprises evaluating the run-time for the first streaming signal recorded on a run clock.

23. The method of claim 17, further comprising the steps of:
determining if a first predetermined amount of time has passed since the first streaming signal was accepted at the digital radio receiver;
accepting the identification code for the digital receiver if the first predetermined amount of time has passed;
evaluating the information about the end-user associated with the identification code to determine at least one sponsor having a product that may be of interest to the end user;
determining if a first segment of the first streaming signal has reached a conclusion;
pausing a transmission of the first streaming signal for the first selected radio feed if the first segment of the first streaming signal has reached a conclusion;
accepting a third advertisement related to the sponsor having a product that may be of interest to the end-user;
playing the third advertisement at the digital radio receiver; and
resuming the transmission of the first streaming signal for the first selected radio feed to the digital radio receiver.

24. The method of claim 23, further comprising the steps of:
determining if a second predetermined amount of time has passed;
accepting the identification code for the digital receiver if the second predetermined amount of time has passed;
evaluating the information about the end-user associated with the identification code to determine at least one sponsor having a product that may be of interest to the end user;
determining if a second segment of the first streaming signal has reached a conclusion;
pausing a transmission of the first streaming signal for the first selected radio feed if the second segment of the first streaming signal has reached a conclusion;
accepting a fourth advertisement related to the sponsor having a product that may be of interest to the end-user;
playing the fourth advertisement at the digital radio receiver; and
resuming the transmission of the first streaming signal for the first selected radio feed to the digital radio receiver.

25. The method of claim 24, wherein determining if the second predetermined amount of time has passed comprises evaluating the run-time for the first streaming signal from the time of activation of the digital radio receiver recorded on a run clock.

26. The method of claim 24, wherein determining if the second predetermined amount of time has passed comprises evaluating the run-time on a run clock for the first streaming signal, from the time the third advertisement was played on the digital radio receiver.

27. The method of claim 17, further comprising the steps of:
accepting an input for a second selected radio feed at a front panel display of the digital radio receiver;
accepting a signal that the radio feed at the digital radio receiver has been changed from the first selected radio feed to the second selected radio feed;
accepting the identification code for the digital radio receiver;
evaluating the information about the end-user associated with the identification code to determine at least one sponsor having a product that may be of interest to the end user;
accepting a fifth advertisement related to the sponsor having a product that may be of interest to the end-user;
playing the fifth advertisement at the digital radio receiver; and
playing the second streaming signal at the digital radio receiver.

28. A method for providing targeted advertising to purchasers of an automobile from a manufacturer through a digital radio receiver installed in the automobile comprising the steps of:
providing a digital radio receiver in the automobile that can only receive advertisements sponsored by the manufacturer of the automobile;
associating an identification code for the digital radio receiver with the age of the automobile accepting a first streaming signal for a first selected radio feed at the digital radio receiver;
playing the first streaming signal at the digital radio receiver;
accepting the identification code for the digital radio receiver;
determining the first predetermined amount of time since the first streaming signal was accepted by evaluating the age of the automobile associated with the identification code, wherein the amount of time between the transmission of advertisements is reduced as the automobile gets older;
determining if the first predetermined amount of time has passed;
accepting a first advertisement sponsored by the manufacturer of the automobile at the digital radio receiver if the first predetermined amount of time has passed;
playing the first advertisement on the digital radio receiver;
accepting the first streaming signal for the first selected radio feed at the digital radio receiver; and
playing the first streaming signal at the digital radio receiver.

29. The method of claim 28, further comprising the steps of:
a. determining if a first segment of the first streaming signal has reached a conclusion if the first predetermined amount of time has passed;
b. continue playing the first streaming signal at the digital radio receiver if the first segment of the first streaming signal has not reached a conclusion;
c. continue steps (a)-(b) until the first segment of the first streaming signal has reached a conclusion;
d. pausing the transmission of the first streaming signal to the digital radio receiver if the first streaming signal has reached a conclusion;
e. accepting the first advertisement sponsored by the manufacturer of the automobile at the digital radio receiver;
f. playing the first advertisement on the digital radio receiver;
g. continuing the transmission of the first streaming signal for the first selected radio feed to the digital radio receiver; and
h. playing the first streaming signal at the digital radio receiver.

30. The method of claim 28, further comprising the steps of:
accepting the identification code for the digital radio receiver;
determining the second predetermined amount of time since the first advertisement was played at the digital radio receiver by evaluating the age of the automobile associated with the identification code, wherein the amount of time between the transmission of advertisements is reduced as the automobile gets older;
determining if the second predetermined amount of time has passed;
accepting a second advertisement sponsored by the manufacturer of the automobile at the digital radio receiver if the second predetermined amount of time has passed;
playing the second advertisement on the digital radio receiver;
accepting the first streaming signal for the first selected radio feed at the digital radio receiver; and
playing the first streaming signal at the digital radio receiver.

31. The method of claim 28, further comprising the steps of:
accepting an input for a second selected radio feed at a front panel display for the digital radio receiver;
accepting a signal that the radio feed has been changed from the first selected radio feed to the second selected radio feed;
accepting a third advertisement sponsored by the manufacturer of the automobile at the digital radio receiver;
playing the third advertisement at the digital radio receiver;
accepting a second streaming signal for the second selected radio feed at the digital radio receiver;
playing the second streaming signal at the digital radio receiver.

32. A method for providing an advertising cocoon in an automobile comprising the steps of providing a plurality of digital radio stations to an automobile, whereby a manufacturer of the automobile controls content received via the plurality of stations in the automobile.

33. The method of claim 32, further comprising the step of a consumer purchasing the automobile selecting the plurality of stations provided to the automobile from a group of stations offered by the manufacturer.

34. The method of claim 32, further comprising the step of the manufacturer of the automobile controlling advertising content provided on the plurality of stations to the automobile.

35. The method of claim 34, wherein controlling advertising content comprises preventing an advertisement from another manufacturer of other automobiles from being transmitted to the automobile via the plurality of stations provided to the automobile.

36. The method of claim 34, wherein controlling advertising content comprises limiting the advertising content provided to the automobile via the plurality of stations to advertisements for the manufacturer of the automobile.

37. The method of claim 32, further comprising the step of transmitting at least one advertisement to the automobile via the plurality of stations when a consumer selects a first station from the plurality of stations.

38. The method of claim 32, further comprising the step of transmitting at least one advertisement to the automobile via the plurality of stations when a consumer initially activates the radio.

39. A method for providing an advertising cocoon in an automobile comprising the steps of:
providing a plurality of digital radio stations to an automobile, whereby a manufacturer of the automobile controls content received from the plurality of stations in the automobile and the manufacturer of the automobile controlling advertising content provided on the plurality of stations to the automobile.

40. The method of claim 39, wherein controlling advertising content comprises preventing an advertisement from another manufacturer of other automobiles from being transmitted to the automobile via the plurality of stations provided to the automobile.

41. The method of claim 40, further comprising the step of transmitting at least one advertisement to the automobile via the plurality of stations when a consumer selects a first station from the plurality of stations.

42. The method of claim 40, further comprising the step of transmitting at least one advertisement to the automobile via the plurality of stations when a consumer initially activates the radio.

43. A method of providing an advertising cocoon in an automobile comprising the steps of:
providing a digital radio receiver in an automobile manufactured by an automobile manufacturer, the receiver capable of receiving a plurality of ad-free radio feeds, wherein the plurality of feeds are only provided to receivers in automobiles manufactured by the manufacturer;
accepting a first streaming signal for a first selected radio feed at the receiver, the radio feed directed to one of a plurality of radio genres and comprising content provided by a disc jockey; and
intermittently providing content about the automobile manufacturer.

44. The method of claim 43, wherein the content about the automobile manufacturer comprises a description of an automobile offered for sale by the automobile manufacturer.

45. The method of claim 43, wherein the content about the automobile manufacturer comprises a statement that the ad-free radio feeds are provided by the automobile manufacturer.

46. A method for providing targeted advertising to an automobile comprising the steps of:
providing a digital radio receiver in the automobile, the receiver comprising a browser capable of receiving at least one Internet radio station;
providing a plurality of wireless fidelity stations capable of being received by the receiver;
providing an advertisement window concurrently on all of the stations;
playing an advertisement within the advertisement window concurrently on all of the stations, wherein the concurrent playing of the advertisement on all of the stations prevents a user from changing the station to avoid hearing the advertisement.

47. The method of claim 46, wherein the content provided during the advertisement window is controlled by a manufacturer of the automobile.

48. A method for providing targeted radio content to an automobile comprising the steps of:
determining if a first content segment was broadcast substantially in its entirety prior to a different channel being selected at a digital radio receiver;
determining a first set of information about the first content segment based on a positive determination that the first segment was broadcast substantially in its entirety;
accepting additional content segments that include the first set of information; and
downloading the additional content segments to the digital radio receiver.

49. The method of claim 48, further comprising the steps of:
determining a first set of information about the first content segment based on a negative determination that the first segment was broadcast substantially in its entirety prior to a different channel being selected; and
preventing the download of additional content segments that include the first set of information at the digital radio receiver.

50. The method of claim 48, wherein the downloading the additional content segments occurs while the digital radio receiver is not in use.

51. The method of claim 48, wherein determining if a first content segment was broadcast substantially in its entirety prior to a different channel being selected further comprises the steps of:
initiating a broadcast of the first content segment at a digital radio receiver;
determining if a first predetermined amount of time has passed since the initiation of the broadcast; and
generating a positive determination that the first content segment was broadcast substantially in its entirety based on a positive determination that the first predetermined amount of time has passed.

52. The method of claim 51, wherein the first predetermined amount of time is less than one minute.
